(19) United States
(12) Patent Application Publication
(10) Pub. No.: US 2007/0277079 A1
(43) Pub. Date: Nov. 29, 2007

(54) Method For Error Correction Of Program-Associated Data

(76) Inventors: Frank Hofmann, Hildesheim (DE); Gerald Spreitz, Laatzen (DE); Gerold Bertram, Hespe (DE)

Correspondence Address: KENYON & KENYON LLP, ONE BROADWAY, NEW YORK, NY, 10004, US

(21) Appl. No.: 11/660,260

(22) PCT Filed: Jul. 19, 2005
(86) PCT No.: PCT/EP05/53494

§ 371 Date: Jul. 10, 2007

(30) Foreign Application Priority Data
Aug. 20, 2004 (DE) 102004040676.6

(51) Int. Cl. H03M 13/00

(52) U.S. Cl. 714/758

(57) ABSTRACT

For error correction of program-associated data in frames, e.g., DAB data packets, with code words being used over multiple data packets, redundancy information for error correction is added while retaining the original frame structure. The information about the length of the program-associated data is additionally protected by a code.

### BACKGROUND OF THE INVENTION

1. Field of the Invention

The present invention relates to a method for error correction of data transmitted in frames.

2. Description of Related Art

For data transmission, the DAB (Digital Audio Broadcasting) standard, for example, specifies a method for transmitting data in groups of variable length within an MPEG frame, the data being associated with audio programs based on its content. These are known as “program-associated data”—PAD. The additional data, in particular that of variable length, is referred to as “X-PAD,” where X stands for extended. This standard does not provide any method of error recognition to recognize data transmitted in error. For some applications, this data is combined into data groups for which an error recognition method (CRC method) is used. Since the individual data bits are combined into groups and then into data files, a single false bit can invalidate the transmission of large volumes of data. The error protection in DAB is achieved by using a convolution code. The goal here was to achieve a bit error rate of 10⁻⁴.

German patent application DE 10 2004 014 594.6 describes a method for error correction of packet data which adds redundancy information to the error correction while retaining the original packet data structure.

In the DVB-T method, a concatenated code of convolution code and block code is used. Very low bit error rates on the order of 10⁻⁸ may be achieved in this way.

### BRIEF SUMMARY OF THE INVENTION

In accordance with the present invention, code words are used over multiple frames and redundancy information is added for error correction while retaining the original data structure, e.g., for program-associated data of variable length, and information about the length of the program-associated data is additionally protected by a code; errors may be corrected without requiring a DAB receiver to have knowledge of this method, so the data is nevertheless recognized as valid DAB-PAD data and may be processed with a conventional error recognition method (e.g., CRC). Higher-quality receivers that use the error correction method according to the present invention may use this method and thus supply correct data files more often and/or more rapidly.

If the information about the length of the program-associated data (X-PAD fields) is additionally protected against transmission errors, the new structure cannot collapse completely in the event of faulty length information.

The present invention is based on the finding that although the bit error rate is low for audio data, it is too high for transmission of program-associated data.

### BRIEF DESCRIPTION OF THE SEVERAL VIEWS OF THE DRAWING

FIG. 1 shows a contiguous data stream of audio data and program-associated data.

FIG. 2 shows a FEC-PAD structure.

FIG. 3 shows a FEC-PAD structure having 192 columns and 12 rows.

FIG. 4 shows a FEC-PAD structure having protection of the length of the program-associated data.

FIG. 5 shows the structure of the content indicator field.

FIG. 6 shows the protection of the length information of the program-associated data.

FIG. 7 shows a 3-bit grouping for the data according to FIG. 6.

FIG. 8 shows the F-PAD structure having additional PAD error protection.

FIG. 9 shows the overall data structure.

### DETAILED DESCRIPTION OF THE INVENTION

Before describing the present invention, structures using conventional error correction will be described below briefly for better understanding of the present invention.

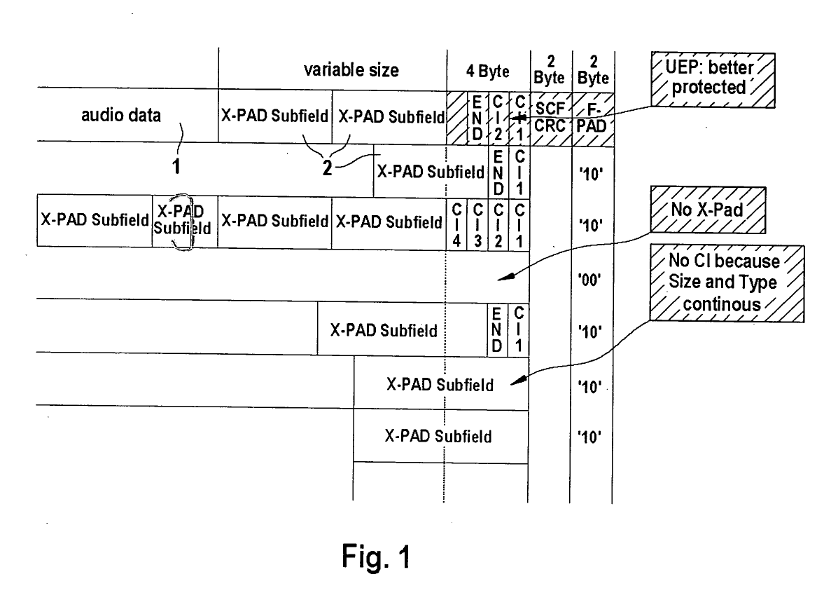

FIG. 1 shows a previous frame structure of audio data to which program-associated data fields are assigned in the form of X-PAD subfields 2 of variable length. These X-PAD subfields 2 are followed by a 4-byte field followed by two 2-byte fields. The 4-byte field is filled with 1-byte content indicators CI and/or an END marker to close the CI list. Depending on the length and/or number of X-PAD subfields, zero to four CI indicators are provided. The CI indicator describes what is contained in the X-PAD subfield. If there are X-PAD subfields 2, this is labeled as “10” in the F-PAD field. If there are no X-PAD subfields, the code “00” will appear in the F (fixed) PAD field. UEP (unequal error protection) means better protection.

The boundary conditions of this method are as follows:
The bit error rate should be less than 10⁻⁸ if the entire audio channel has a BER of 10⁻⁴.
Existing services should not be influenced, including simple services such as “dynamic label” (reverse compatibility level 2),
X-PAD applications of variable length are to be supported,
Sudden termination of data is to be supported with a variable end of the FEC (forward error correction) frame.

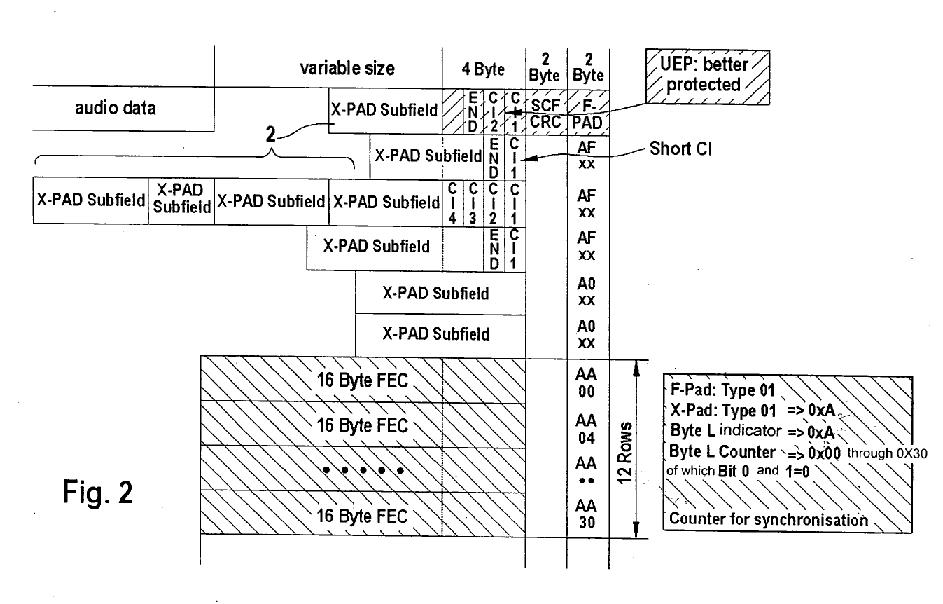

FIG. 2 shows the FEC-PAD structure, where 16-byte fixed-length FED fields are arranged in 12 columns for error correction. Signaling is performed within the F-PAD field (byte-L indicator/L-byte data field). Furthermore, a counter is provided for identifying the frame in the F-PAD field to locate the position of the code words unambiguously.

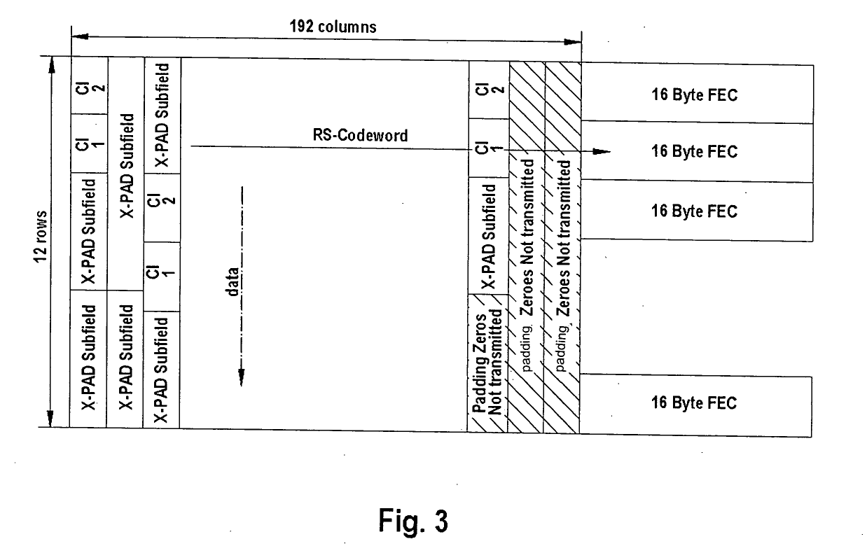

FIG. 3 shows the FEC-PAD structure in a matrix having 192 columns and 12 rows. Only relevant data is protected. “Padding zeros” are not transmitted. Additional parity data is inserted as new X-PAD FEC data. All other data having PAD is not affected. Consequently all X-PAD applications are available and usable for traditional receivers. Robust synchronization and signaling of FEC data are provided in the F-PAD field. Data is assigned in an “application data table” as in the packet mode method. The same frame structure and coding are used to limit the complexity of the receiver. The FEC frame may be terminated at any time to support interruptions in the X-PAD transmission. However, there is one main problem: just one bit error in the length indicators (CI indicators) of X-PAD subfields is capable of destroying the entire FEC frame despite the higher level of protection by UEP.

To prevent this, the information about the length of the program-associated data (CI indicators) is protected by an additional code according to the present invention.

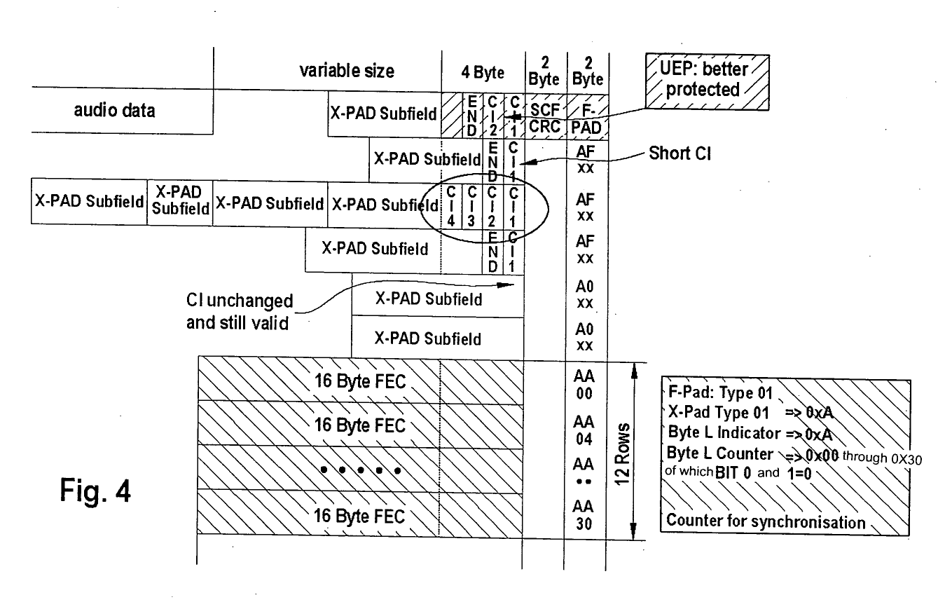

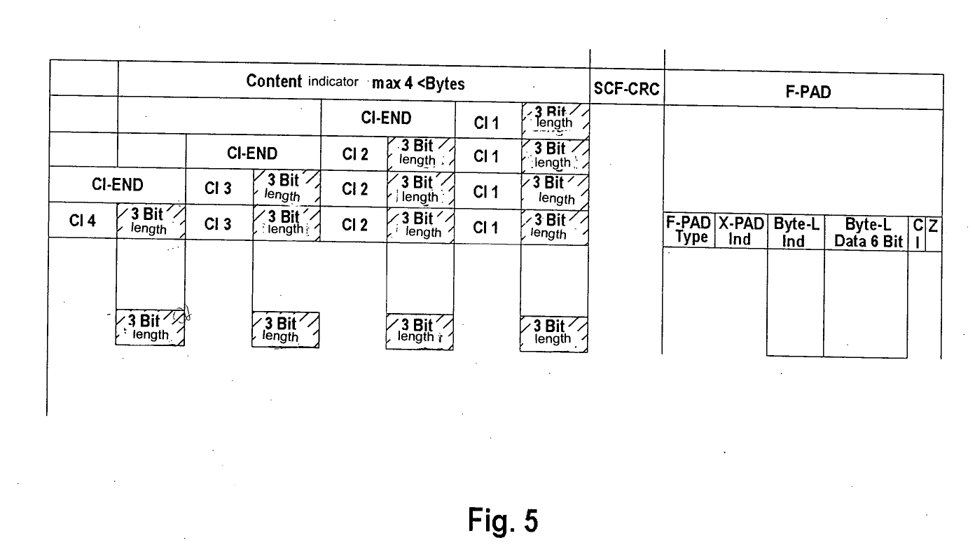

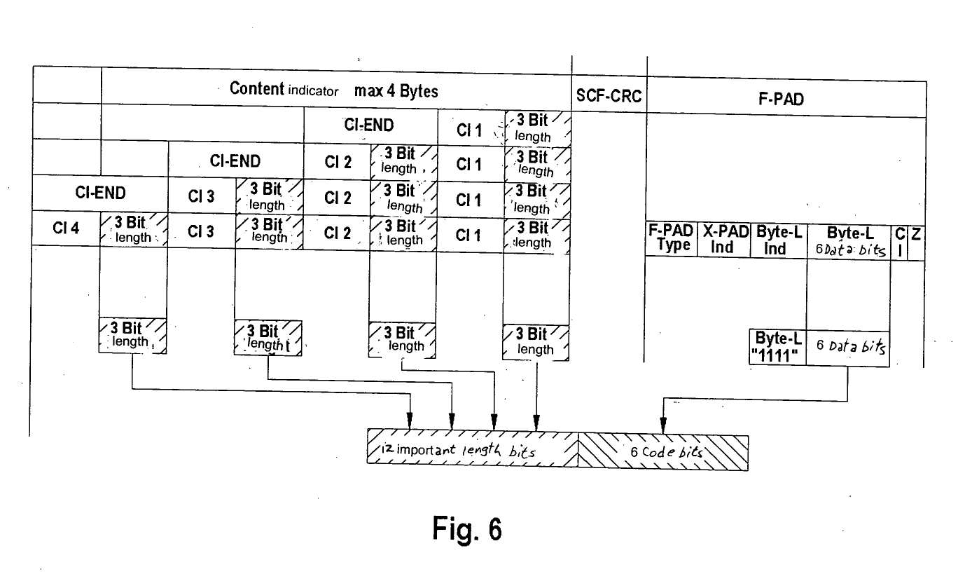

The length information (CI indicators) circled in FIG. 4 is shown on an enlarged scale in FIG. 5. There are 4 groups of 3-bit length information (total 12 bits) that are protected according to FIG. 6.

To do so, 6 data bits are added as parity bits in the F-PAD “byte-L” field. A simple block code (18, 12) is only capable of correcting 1 bit. This is not enough if a Viterbi Codec generates an error burst. Coding of length information using a Reed Solomon code (RS code) calculated using a Galois field (2³) is better. In other words, the 3-bit length information is grouped into 4 information symbols, which together with 2 parity symbols are encoded using an RS code over the Galois field GF (2³). An RS (6, 4) code is impossible. However, an RS (7, 5) code may be used, shortened (by one) to the packet length used. Using this code, a symbol (a 3-bit group) may be corrected so that the code is more rugged with respect to burst fields.

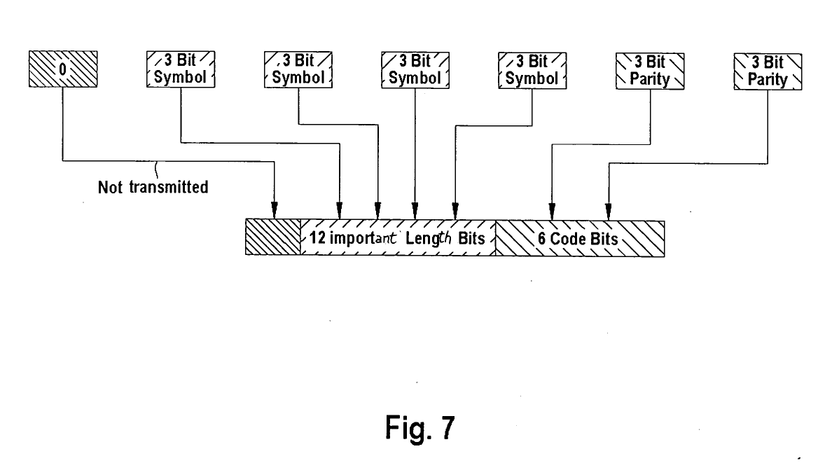

FIG. 7 shows the grouping of the CI data. An RS (7, 5, 3) code is provided. The first symbol is set at 0 and is not transmitted. This is followed by 4 information symbols and 2 parity symbols.

This is followed by four information symbols and two parity symbols. It is advantageous to correct all the 4-bit groups, regardless of whether or not they contain length information.

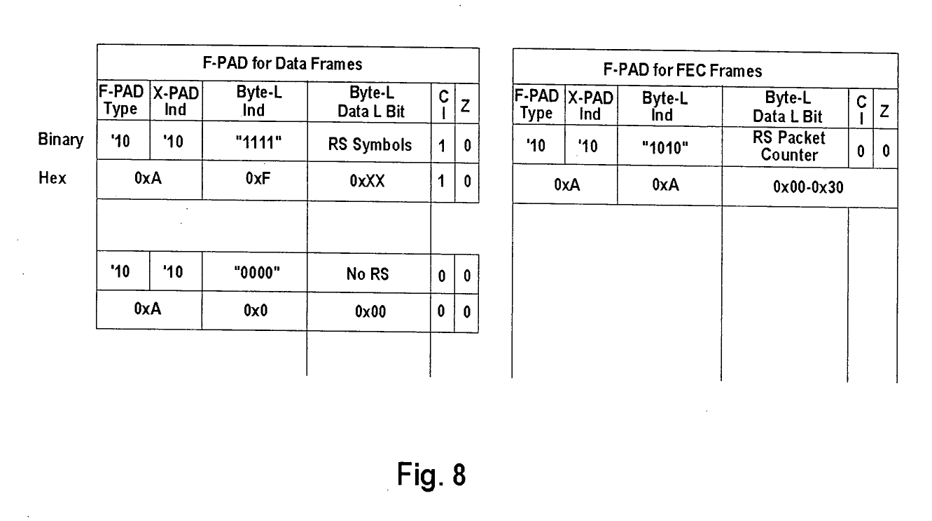

FIG. 8 shows the identification/signaling in the F-PAD field with newly defined L-byte indicators, e.g., for protected CI data:
byte-L ind=′b 1111,
   e.g., for FEC frames:
byte-L ind=′b 1010.

For FEC frames, a counter Z is provided for synchronization in the L-byte data field. For data frames, parity bits are inserted into the L-byte data field; these parity bits are necessary for correct detection of PAD bits.

FIG. 9 shows the overall data structure.

1-12. (canceled)

13. A method for error correction of data transmitted in frames, wherein code words are used over multiple frames, comprising:
providing a redundancy information for error correction while retaining original frame structure for program-associated data of a variable length; and
additionally protecting information about the length of the program-associated data by an additional code.

14. The method as recited in claim 13, wherein DAB-X-PAD data packets are used as the program-associated data.

15. The method as recited in claim 14, wherein the additional code for protecting the length information of the DAB-X-PAD data is provided in L-byte data field inside F-PAD field.

16. The method as recited in claim 14, wherein the existence of the additional code for protecting the length information is indicated.

17. The method as recited in claim 16, wherein the indication of the existence of the additional code is provided in F-PAD field.

18. The method as recited in claim 14, wherein a Reed-Solomon Code is used for error correction of the information about the length of the program-associated data, and wherein the Reed-Solomon Code is calculated via Galois field 23.

19. The method as recited in claim 14, wherein for error correction of the information about the length of the program-associated data, all 4-bit groups in content indicator field are corrected, regardless of whether the 4-bit groups contain length information.

20. The method as recited in claim 17, wherein an identification is provided in the F-PAD field for at least one of: a) identifying that the redundancy information for error correction is contained in a frame; and b) identifying the position of the code words in a data stream.

21. The method as recited in claim 20, wherein, in addition to the identification, a counter is provided in the F-PAD field to unambiguously identify the position of the code words.

22. The method as recited in claim 18, wherein a Reed-Solomon code that is shortened to packet lengths used in the data transmission is used for error correction.

23. The method as recited in claim 14, wherein a separate data packet which is provided for the redundancy information is appended to data packets for useful information.

24. The method as recited in claim 23, wherein the transmission of useful data is configured to be terminated at any desired point in time to send the redundancy information.
